(19) United States
(12) Patent Application Publication
(10) Pub. No.: US 2017/0299237 A1
(43) Pub. Date: Oct. 19, 2017

(54) SOLAR-POWERED SYSTEM

(71) Applicant: Andrew Xianyi Huang, Arcadia, CA (US)

(72) Inventor: Andrew Xianyi Huang, Arcadia, CA (US)

(21) Appl. No.: 15/402,948

(22) Filed: Jan. 10, 2017

Related U.S. Application Data
(60) Provisional application No. 62/323,707, filed on Apr. 17, 2016.

(51) Int. Cl. F25B 21/04; F25B 27/00; H02S 40/44; H01L 35/30; H02S 40/42

(52) U.S. Cl. CPC F25B 21/04; H01L 35/30; H02S 40/425; H02S 40/44; F25B 27/002

(57) ABSTRACT

A solar-powered system that can be used in a predetermined space includes a plurality of solar panels to convert the sunlight into electrical energy; a thermoelectric device electrically connected with the solar panels to provide a hot surface and a cold surface; and a control module to control the temperature in the predetermined space. The solar-powered system is configured to cool down or heat up the temperature in the predetermined space. In one embodiment, the thermoelectric module is a Peltier device.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

### Field of Invention

The present invention related to a solar-powered system, and more particularly to a solar-powered system that can be used to continuously cool down and warm up the environment inside an area.

### Description of Related Arts

Every year, thousands of people suffer from heat-related and cold-related illnesses. For example, numbers of baby and elderly die from hyperthermia and hypothermia during winter or summer time. Especially in recent years, greenhouse effect has become more and more serious, so the global environment has become extremely cold and hot in winter and summer respectively. Therefore, various devices used to cool down or warm up the temperature inside a predetermined area have been developed.

An air conditioner is a commonly used device to cool down the temperature, but it is a high energy consuming machine, especially the compressor thereof driven by a motor to drive the refrigerant being circulated in a sealed system. However, the cooling efficiency of the compressor is usually not high enough, and the stability of the mechanical operating system of the air conditioner is concerned. In addition, the noise level generated by the mechanical operating system of the air conditioner is high. Furthermore, most of the refrigerant is not environment friendly material, so our environment may be polluted by the residual refrigerant.

In a vehicle setting, it is impossible to turn off the air conditioner inside the vehicle during the hot while driving. In addition, the outlets of the air conditioner inside the vehicle are usually arranged adjacent to the engine (adjacent to the front seats), so the efficiency of the air condition is usually not enough to rapidly cool down the vehicle, and the driver and passengers may have to suffer the hot temperature for a while inside the vehicle. Therefore, there remains a need for a new and improved device to effectively cool down and warm up the temperature in a predetermined size of area.

### SUMMARY OF THE PRESENT INVENTION

The invention is advantageous in that it provides a solar-powered system adapted to effectively cool down or warm up a predetermined area, such as in a car, which is triggered merely by the solar energy, so it is clean and environment friendly.

Another advantage of the invention is to provide a solar-powered system, wherein the solar-powered system comprises a Peltier device, and a plurality of solar panels adapted to generate the electricity to the Peltier device for cooling down or warming up the temperature the predetermined area.

Another advantage of the invention is to provide a solar-powered system, wherein the performance of the solar-powered system is based on a thermoelectric device, such as a Peltier device, so no chemical component is needed in the solar-powered system to prevent the environment being polluted.

Another advantage of the invention is to provide a solar-powered system, wherein the solar panels are not only able to provide the electricity to the Peltier device, but also able to provide electricity to the batteries of the vehicle.

Another advantage of the invention is to provide a solar-powered system, wherein no noise is generated while the solar-powered system is operating, so it is very comfortable for the user to stay around the area where the solar-powered system is in function.

Another advantage of the invention is to provide a solar-powered system which comprises a control module having a heating module and a cooling module which are activated to control the Peltier device to cool down or warm up the temperature of the predetermined area.

Another advantage of the invention is to provide a solar-powered system, wherein the control module comprises a temperature presetting module to preset a standard temperature and a temperature sensor to detect the temperature inside the object, and the temperature inside the object is adapted to compare with the standard temperature for selectively activating the Peltier device to cool down or warm up the area.

Another advantage of the invention is to provide a solar-powered system, wherein the solar-powered system can be implemented in various places in a vehicle, such as a car seat cover, a car seat/booster, and in any predetermined place in the vehicle, so the solar-powered system can be versatile in terms of usage.

Additional advantages and features of the invention will become apparent from the description which follows, and may be realized by means of the instrumentalities and combinations particular point out in the appended claims.

In one aspect, a solar-powered system in the present invention is adapted to use in an object, such as small-size vehicle or cabins, to control the temperature inside the object. In one embodiment, the solar-powered system comprises a plurality of solar panels, a thermoelectric module electrically connected with the solar panels, and one or more heat sinks connected to the thermoelectric module. The solar panels are adapted to absorb and collect solar energy from the sun, and then convert the solar energy into electrical energy.

In an exemplary embodiment, the solar panels are electrically connected with the thermoelectric module through wires, wherein the electricity generated by the solar panels is transmitted to the thermoelectric module through the wires to activate the thermoelectric module. The thermoelectric module, in one embodiment, may be a Peltier device including a cold surface end and a hot surface, which are also called a heat absorbed end (cold surface) and a heat emitted end (hot surface) respectively, after the Peltier device receives the electricity transmitted from the solar panels. In one embodiment, the cold surface end of the Peltier device, which has a lower temperature, can be disposed to face towards an inner space of the object, while the outer end of the Peltier device can be disposed to face outside the object, so when the fans is disposed close to the cold surface to generate a breeze inside the object, a cold breeze can be generated therein.

In general, the efficiency of the solar panels is around 8%, which is quite low, but each square meter of the solar panels can generate 20 watts of power to generate 40° C. difference between the temperature of the heat absorbed end and the heat emitted end. If more electricity is provided to the Peltier device, the difference of the temperature between the heat absorbed end and the heat emitted end becomes greater, and a much better cooling effect can be generated inside the object.

The solar-powered system may include a first heat sink and a second heat sink, which are connected with the heat absorbed end (cold surface) and the heat emitted end (hot surface) respectively. The first heat sink is adapted to allow the cold generated from the Peltier device to be spread over the inner space of the object, while the second heat sink is adapted to allow the heat generated by the Peltier device to be dissipated without the use of electricity. In one embodiment, the solar-powered system further comprises a fan electrically connected with the solar panels, and the electricity generated from the solar panels can be used to power the fan to generate a breeze for improving the convection inside the inner space of the object to rapidly lower the temperature therein.

The solar-powered system further comprises a control module connected with the solar panels, wherein the control module comprises a temperature sensor to detect the temperature inside the object and a temperature adjusting unit to control the temperature of inner space of the object. More specifically, when the temperature sensor detects that the temperature inside the object is greater than a threshold temperature, it can generate and send out a signal to the temperature adjusting unit, and then the temperature adjusting unit is configured to electrically communicate with the solar panels to provide more electricity generated from the solar panels to the Peltier device to increase the temperature difference between the cold surface and the hot surface to lower the temperature in the object. On the contrary, if the temperature inside the object is lower than the threshold temperature, the temperature adjusting unit is again activated to generate another signal to the solar panels to reduce the electricity generated from the solar panels to the Peltier device to slow down the cooling effect inside the object. It is worth mentioning that if the temperature inside the object is the same as the threshold temperature, no signal is transmitted to the solar panels, and no electricity is provided to the Peltier device, so the entire solar-powered system is off to prolong the life-span of the solar-powered system of the present invention.

These and other objectives, features, and advantages of the present invention will become apparent from the following detailed description, the accompanying drawings, and the appended claims.

### BRIEF DESCRIPTION OF THE DRAWINGS

FIG. 1 is a block diagram showing a preferred embodiment in the present invention.

FIG. 2 is a schematic view of the solar-powered system in the present invention inside a vehicle.

FIGS. 3a and 3b are schematic views of the solar-powered system in the present invention disposed on a carseat.

FIG. 4 illustrates an experiment setup to demonstrate the solar-powered system in the present invention.

### DETAILED DESCRIPTION OF THE PREFERRED EMBODIMENT

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

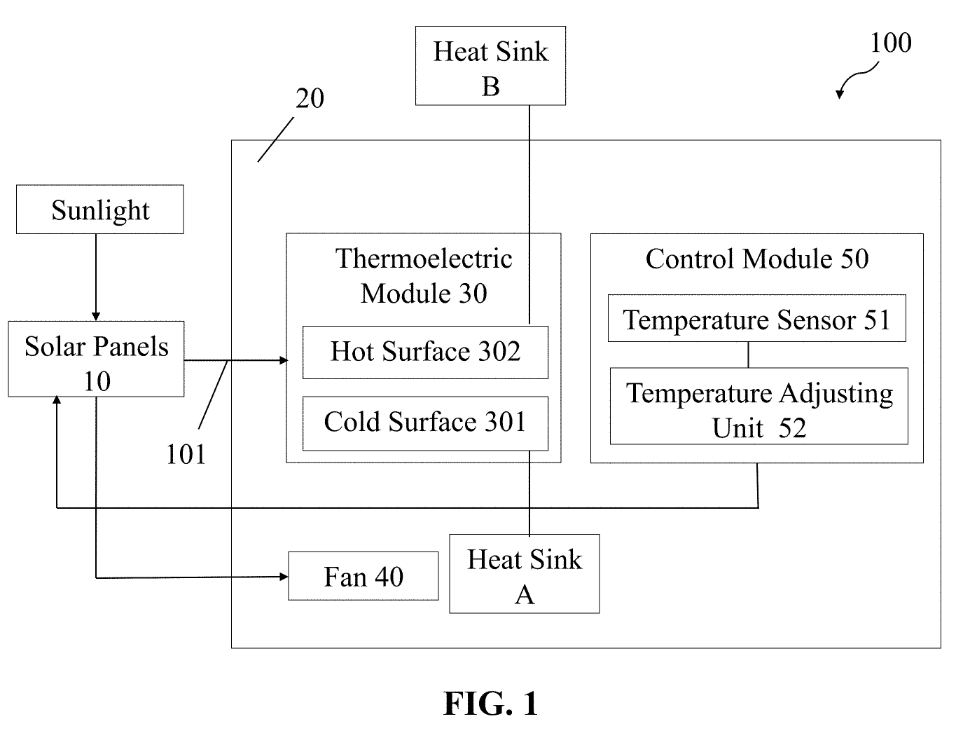

Referring to FIG. 1, a solar-powered system 100 according to one aspect of the present invention is illustrated. In one embodiment, the solar-powered system is adapted to use in an object 20, such as small-size vehicle or cabins, to control the temperature inside the object 20.

In one embodiment, the solar-powered system 100 comprises a plurality of solar panels 10, a thermoelectric module 30 electrically connected with the solar panels 10, and heat sinks A and B connected to the thermoelectric module 30. The solar panels 10 are adapted to absorb and collect solar energy from the sun, and then convert the solar energy into electrical energy.

It is known that the Peltier device uses the Peltier effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current. Such an instrument is also called a Peltier heat pump, solid state refrigerator, or thermoelectric cooler (TEC).

In an exemplary embodiment, the solar panels 10 are electrically connected with the thermoelectric module 30 through wires 101, wherein the electricity generated by the solar panels 10 is transmitted to the thermoelectric module 30 through the wires 101 to activate the thermoelectric module 30. The thermoelectric module 30, in one embodiment, may be a Peltier device including a cold surface end 301 and a hot surface 302, which are also called a heat absorbed end (cold surface) and a heat emitted end (hot surface) respectively, after the Peltier device 30 receives the electricity transmitted from the solar panels 10. In one embodiment, the cold surface end 301 of the Peltier device 30, which has a lower temperature, can be disposed to face towards an inner space of the object 20, while the outer end 302 of the Peltier device 30 can be disposed to face outside the object 20, so when the fans 40 (described below) is disposed close to the cold surface 301 to generate a breeze inside the object 20, a cold breeze can be generated therein.

In general, the efficiency of the solar panels 10 is around 8%, which is quite low, but each square meter of the solar panels can generate 20 watts of power to generate 40° C. difference between the temperature of the heat absorbed end and the heat emitted end. If more electricity is provided to the Peltier device 30, the difference of the temperature between the heat absorbed end and the heat emitted end becomes greater, and a much better cooling effect can be generated inside the object 20.

The solar-powered system 100 may include a heat sink A and a heat sink B, which are connected with the heat absorbed end (cold surface) 301 and the heat emitted end (hot surface) 302 respectively. The heat sink A is adapted to allow the cold generated from the Peltier device 30 to be spread over the inner space of the object 20, while the heat sink B is adapted to allow the heat generated by the Peltier device 30 to be dissipated without the use of electricity. In one embodiment, the solar-powered system further comprises a fan 40 electrically connected with the solar panels 10, and the electricity generated from the solar panels 10 can be used to power the fan 40 to generate a breeze for improving the convection inside the inner space of the object 20 to rapidly lower the temperature therein.

The solar-powered system 100 further comprises a control module 50 connected with the solar panels 10, wherein the control module 50 comprises a temperature sensor 51 to detect the temperature inside the object 20 and a temperature adjusting unit 52 to control the temperature of inner space of the object 20. More specifically, when the temperature sensor 51 detects that the temperature inside the object 20 is greater than a threshold temperature T, it can generate and send out a signal to the temperature adjusting unit 52, and then the temperature adjusting unit 52 is configured to electrically communicate with the solar panels 10 to provide more electricity generated from the solar panels 10 to the Peltier device 30 to increase the temperature difference between the cold surface and the hot surface to lower the temperature in the object 20. On the contrary, if the temperature inside the object 20 is lower than the threshold temperature T, the temperature adjusting unit 52 is again activated to generate another signal to the solar panels 10 to reduce the electricity generated from the solar panels 10 to the Peltier device 30 to slow down the cooling effect inside the object 20. It is worth mentioning that if the temperature inside the object 20 is the same as the threshold temperature T, no signal is transmitted to the solar panels 10, and no electricity is provided to the Peltier device 30, so the entire solar-powered system is off to prolong the life-span of the solar-powered system of the present invention.

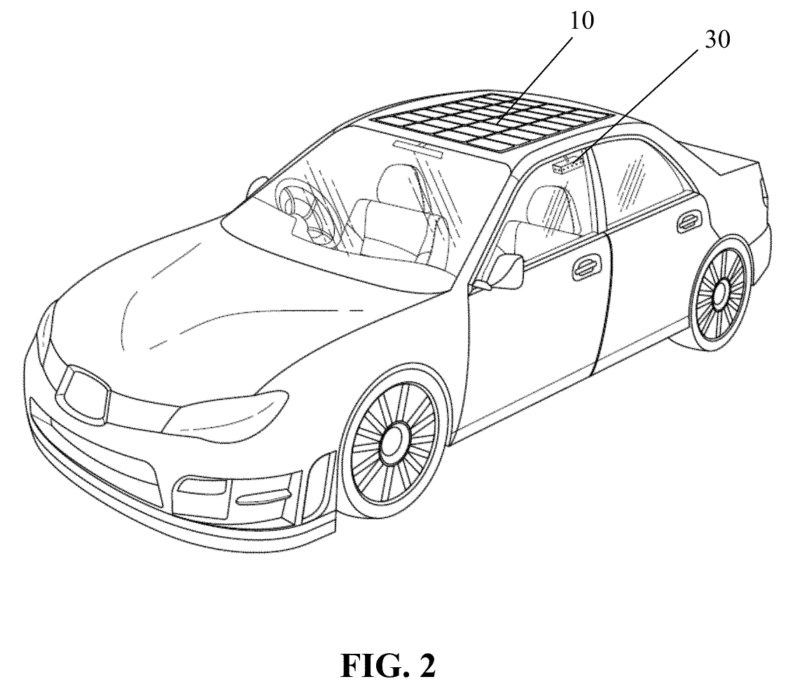

Preferably, the solar-powered system can be implemented to a vehicle as shown in FIG. 2. Since the whole solar-powered system only requires solar energy, no external energy is required to power the solar-powered system in the present invention, so the vehicle engine does not have to be on to activate the solar-powered system to provide a more efficiency way to cool down the temperature inside the vehicle. Furthermore, the electricity generated from the solar panels can provide to power the batteries of the vehicle, so the life-span of the batteries of the vehicle is prolonged, and it is able to prevent the accidents that the batteries are out of function.

Control module 50 is powered by a rechargeable battery, which may be recharged by solar panels 10 and last enough time to keep control module 50 functional.

Alternatively, the object 20 can be a cover, wherein the cover can be adapted to cover on car seats, boosters, or pet cages/containers, and the solar-powered system is adapted to cool down the temperature inside the cover, so as to not only maintain a comfortable temperature inside the cover, but also to prevent any dangerous situation caused by the extreme higher/lower temperature.

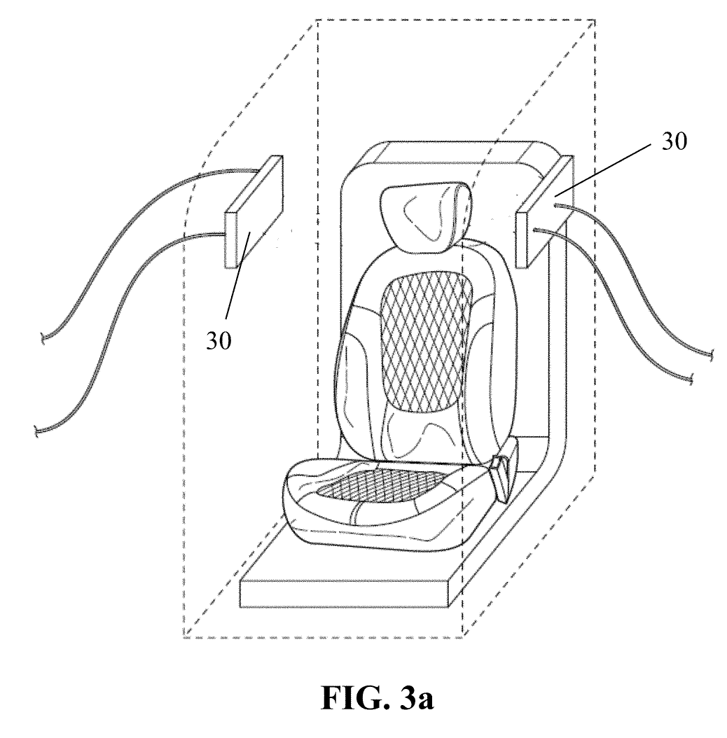

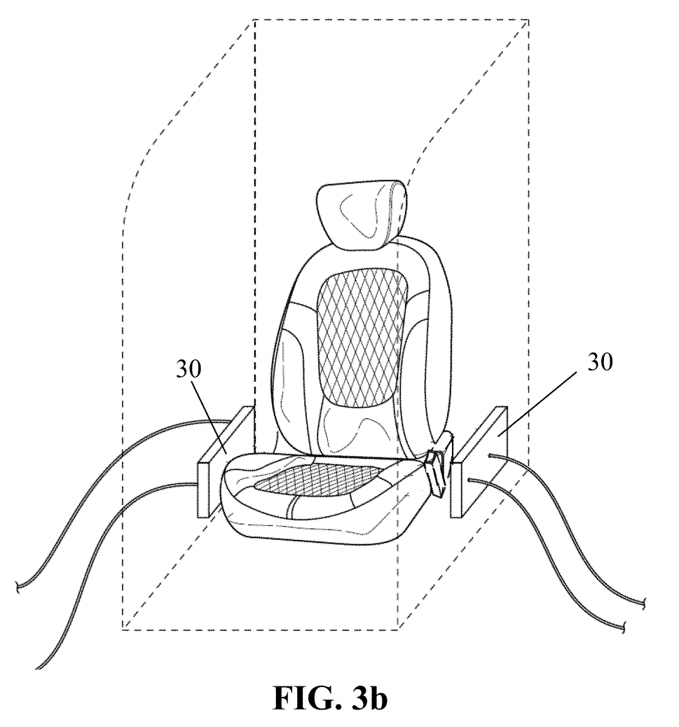

Alternatively, the object 20 can be any kinds of car seats or boosters as shown in FIGS. 3a and 3b, and the solar-powered system is embedded therein to generate a cool air from the fan 40 to cool down the temperature around the car seats or boosters, so that the children and babies may feel more comfortable when sitting on the car seats or boosters.

### EXPERIMENTS

To demonstrate that the solar-powered system in the present invention can be used to cool down or warm up a predetermined area, an experiment was conducted and the results are shown in the discussions below.

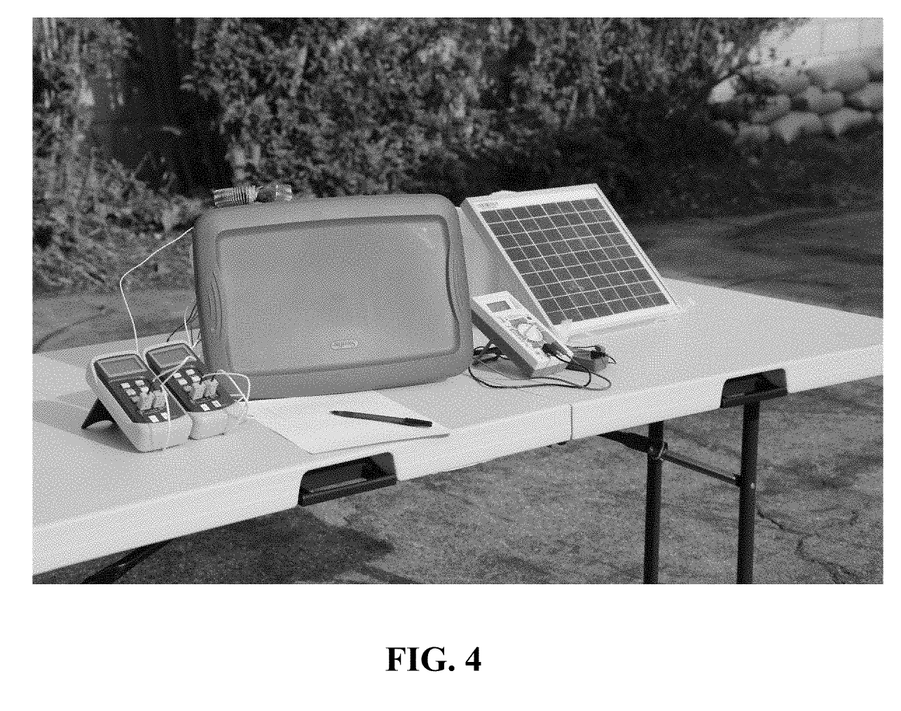

FIG. 4 shows the experiment setup of the solar-powered system. The size of the solar panel is about 11 inch×13 inch, and since the weather on the experiment day is slightly cloudy, the efficiency of the solar panel is about 11%. The solar panel is electrically connected to an electricity meter to measure the current generated by the solar panel and then connected to the Peltier inside the red box. The temperature of the Peltier can be measured by at least one thermometer. The environment temperature may be measured by another thermometer. The results of the experiment is shown in the Table below:

| Time | Voltage | Current | T₁ | T₂ | T₃ | T₄ |
|---|---|---|---|---|---|---|
| 1:00 pm | 2.11 | 0.43 | 26.2 | 19.8 | 21.1 | 25.5 |
| 1:30 pm | 2.27 | 0.46 | 25.1 | 17.4 | 20.1 | 25.6 |
| 2:00 pm | 2.93 | 0.58 | 28.9 | 19.5 | 20.4 | 29.2 |
| 2:30 pm | 2.06 | 0.43 | 27.3 | 21.4 | 21.3 | 26.4 |
| 3:00 pm | 2.17 | 0.45 | 26.1 | 18.7 | 19.2 | 23.6 |

The experiment was conducted from 1 pm to 3 pm and the data were taken every thirty minutes, which includes the voltage and current generated from the solar panel, the temperature of the hot side of the Peltier (T₁), the cold side of the Peltier (T₂), inside the red box (T₃), and outside the red box (T₄).

The voltage/current gradually increases from 1 pm to 2 pm because of the increase of the intensity of the sunlight received by the solar panel, which is evidenced by the increase of the environment temperature (T₄), which goes up from 25.5 to 29.2 (° C.). More specifically, the voltage/current increases from 2.11/0.43 to 2.93/0.58, which generates a higher temperature difference on the

Peltier from 6.4 to 9.4 (° C.), which is agreeable with that if more electricity is provided to the Peltier, the difference of the temperature between the heat absorbed end and the heat emitted end becomes greater.

Furthermore, comparing T₂ and T₄, namely the temperature of the cold side of the Peltier and the environment temperature, the difference increases from 5.7 to 9.7 (° C.) while the environment temperature is increasing, which means that if a fan is equipped on the cold side of the Peltier, a person can enjoy a colder breath of the wind if the outside temperature is higher.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A solar-powered system disposed in a predetermined space, comprising:
a plurality of solar panels to convert sunlight to electrical energy;
a thermoelectric device electrically connected with said solar panels; said thermoelectric device having a cold surface and a hot surface; and
a fan configured to provide a breeze to improve convection in the space;
wherein the thermoelectric device receives the electrical energy from the solar panels to lower temperature of the cold surface disposed in the space, and the fan provides the breeze toward the cold surface to lower the temperature in the space.

2. The solar-powered system of claim 1, further comprising a first heat sink and a second heat sink, which are connected with cold surface and hot surface respectively, wherein the first heat sink is adapted to allow the cold generated from the thermoelectric device to be spread over the space, while the second heat sink is adapted to allow the heat generated by the thermoelectric device to be dissipated without the use of electricity.

3. The solar-powered system of claim 1, wherein said thermoelectric module is a Peltier device.

4. The solar-powered system of claim 1, further comprising a control module connected with the solar panels, wherein the control module comprises a temperature sensor to detect the temperature in the space and a temperature adjusting unit to control the temperature therein. The control module is powered by a rechargeable battery, which may be recharged by the solar panels.

5. The solar-powered system of claim 4, wherein when the temperature sensor detects that the temperature inside the space is greater than a threshold temperature, a signal is generated and transmitted to the temperature adjusting unit, which is configured to electrically communicate with the solar panels to provide more electricity generated from the solar panels to the thermoelectric device to further lower the temperature of the cold surface in the space.

6. The solar-powered system of claim 5, wherein when the temperature inside the space is lower than the threshold temperature, the temperature adjusting unit is activated to generate another signal to the solar panels to reduce the electricity generated therefrom to the thermoelectric device to slow down the cooling effect inside the space.

7. The solar-powered system of claim 2, wherein said thermoelectric module is a Peltier device.

8. The solar-powered system of claim 7, further comprising a control module connected with the solar panels, wherein the control module comprises a temperature sensor to detect the temperature in the space and a temperature adjusting unit to control the temperature therein.

9. The solar-powered system of claim 8, wherein when the temperature sensor detects that the temperature inside the space is greater than a threshold temperature, a signal is generated and transmitted to the temperature adjusting unit, which is configured to electrically communicate with the solar panels to provide more electricity generated from the solar panels to the thermoelectric device to further lower the temperature of the cold surface in the space.

10. The solar-powered system of claim 9, wherein when the temperature sensor detects that the temperature inside the space is lower than a threshold temperature, a signal is generated and transmitted to the temperature adjusting unit, which is configured to electrically communicate with the solar panels to provide less electricity generated from the solar panels to the thermoelectric device to reduce the cooling power, or invert the electric current direction and heat up the inside space if necessary.

11. The solar-powered system of claim 1, wherein the predetermined space is in a vehicle.
